(19) United States
(12) Patent Application Publication
(10) Pub. No.: US 2023/0256546 A1
(43) Pub. Date: Aug. 17, 2023

(54) LASER REFLOW METHOD

(71) Applicant: DISCO CORPORATION, Tokyo (JP)

(72) Inventors: Teppei NOMURA, Tokyo (JP); Yuki IKKU, Tokyo (JP); Zhiwen CHEN, Tokyo (JP)

(21) Appl. No.: 18/162,466

(22) Filed: Jan. 31, 2023

(30) Foreign Application Priority Data
Feb. 17, 2022 (JP) 2022-023241

(51) Int. Cl. B23K 26/57; B23K 26/046; H01L 23/00

(52) U.S. Cl. CPC B23K 26/57; B23K 26/046; H01L 24/75; H01L 24/81; H01L 2224/75263; H01L 2224/81224

(57) ABSTRACT

A laser reflow method includes a preparation step of preparing a workpiece including a board and semiconductor chips that each have bumps formed on one surface thereof and are placed on the board with the bumps interposed therebetween and a laser beam irradiation step of irradiating the semiconductor chips with a laser beam from a side of another surface opposite to the one surface, thereby reflowing bumps formed within an irradiated area of the workpiece. In the laser beam irradiation step, the irradiation with the laser beam is carried out while an irradiation range of the laser beam is changed in stages from a region including an outer peripheral portion of the irradiated area toward a region including a central portion of the irradiated area.

### BACKGROUND OF THE INVENTION

### Field of the Invention

The present invention relates to a laser reflow method.

### Description of the Related Art

In a semiconductor device manufacturing process, as a method for electrically connecting chips and external terminals to each other, there has been known a flip-chip packaging technology in which electrodes on the chips are placed to face and connect to electrodes on a package board with bumps interposed therebetween.

In general, the flip-chip packaging technology adopts, for example, a mass reflow process for heating a board in its entirety to bond chips to the board or a thermo-compression bonding (TCB) process for heating and compressing chips to bond them to a board. However, the mass reflow process has a problem that it causes thermal stress due to the heating of the entire board, and the TCB process has a problem that it takes time to cool a bonder head, for example, and has poor productivity.

As a process that is more advantageous than the above processes, there is known a laser reflow process in which chips are connected to electrodes on a board through laser irradiation (refer to Japanese Patent Laid-open No. 2008-177240 and Japanese Patent Laid-open No. 2021-102217). The laser reflow process is advantageous in that it causes smaller thermal stress than in the case of the mass reflow process because the board is not heated in its entirety, and achieves higher productivity than in the case of the TCB process by applying a laser beam to a plurality of chips.

### SUMMARY OF THE INVENTION

However, it has been found that the laser reflow process causes slightly more bonding failures at outer peripheral portions of chips than those of the other processes. The present applicant and others having investigated into factors of this problem infer that, due to a difference in heat conductivity between a central portion and an outer peripheral portion of a chip, the chip is bonded first at the central portion and a chip warpage occurs, resulting in a bonding failure at the outer peripheral portion.

Accordingly, it is an object of the present invention to provide a laser reflow method which can restrain connection failures from occurring at outer peripheral portions of semiconductor chips.

In accordance with an aspect of the present invention, there is provided a laser reflow method including a preparation step of preparing a workpiece including a board and semiconductor chips that each have bumps formed on one surface thereof and are placed on the board with the bumps interposed therebetween and a laser beam irradiation step of irradiating the semiconductor chips with a laser beam from a side of another surface opposite to the one surface, thereby reflowing bumps formed within an irradiated area of the workpiece. In the laser beam irradiation step, the irradiation with the laser beam is carried out while an irradiation range of the laser beam is changed in stages from a region including an outer peripheral portion of the irradiated area toward a region including a central portion of the irradiated area.

Preferably, in the laser beam irradiation step, a power density of the laser beam is changed in association with the change of the irradiation range.

Preferably, in the laser beam irradiation step, the power density is set such that, with the irradiation range changed in stages, the power density of the laser beam applied to a predetermined irradiation range is equal to or smaller than the power density of the laser beam applied to another irradiation range that is closer to the outer peripheral portion than the predetermined irradiation range.

According to the present invention, it is possible to restrain connection failures from occurring at outer peripheral portions of semiconductor chips.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1 is a flowchart illustrating a flow of a laser reflow method according to an embodiment of the present invention;

FIG. 2 is a perspective view of a workpiece prepared in a preparation step illustrated in FIG. 1;

FIG. 3 is a cross-sectional view of essential parts of the workpiece illustrated in FIG. 2;

FIG. 4 is a cross-sectional view of the essential parts of the workpiece in a state observed during a laser beam irradiation step illustrated in FIG. 1;

FIG. 5 is a view illustrating a configuration example of an optical system of a laser reflow apparatus which carries out the laser beam irradiation step illustrated in FIG. 1;

FIG. 6 is a plan view illustrating a first-stage irradiation range in an irradiated area of the workpiece;

FIG. 7 is a plan view illustrating a second-stage irradiation range in the irradiated area of the workpiece;

FIG. 8 is a plan view illustrating a third-stage irradiation range in the irradiated area of the workpiece;

FIG. 9 is a plan view illustrating a fourth-stage irradiation range in the irradiated area of the workpiece; and

FIG. 10 is a plan view illustrating an irradiation range according to a comparative example.

### DETAILED DESCRIPTION OF THE PREFERRED EMBODIMENT

Preferred embodiment of the present invention will be described in detail below with reference to the accompanying drawings. It is to be noted that the present invention is not limited to the details of the embodiment described below. Further, the constituent elements described below cover those which could easily be envisaged by those skilled in the art and those which are essentially identical to those described. Moreover, arrangements described below can be used in appropriate combinations. Various omissions, replacements, or changes of the arrangements may be made without departing from the scope of the present invention.

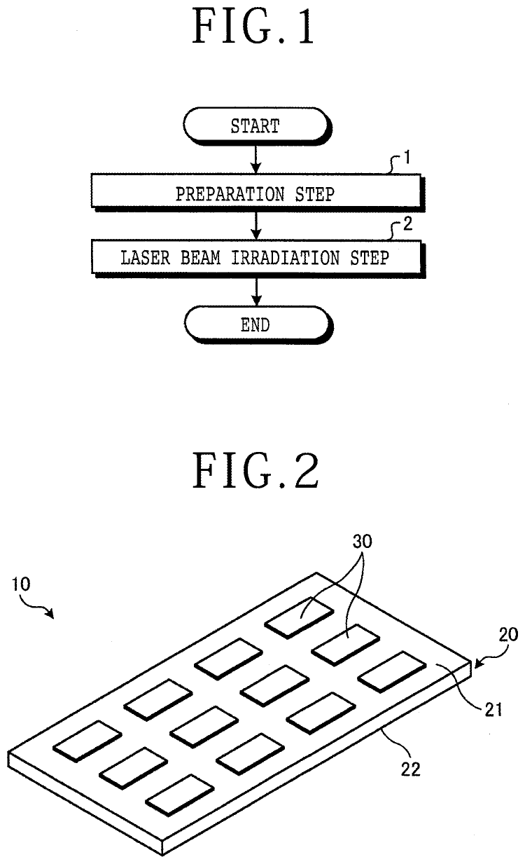

First, a laser reflow method according to an embodiment of the present invention will be described with reference to the accompanying drawings. FIG. 1 is a flowchart illustrating a flow of the laser reflow method according to the embodiment. As illustrated in FIG. 1, the laser reflow method includes a preparation step 1 and a laser beam irradiation step 2.

(Preparation Step 1)

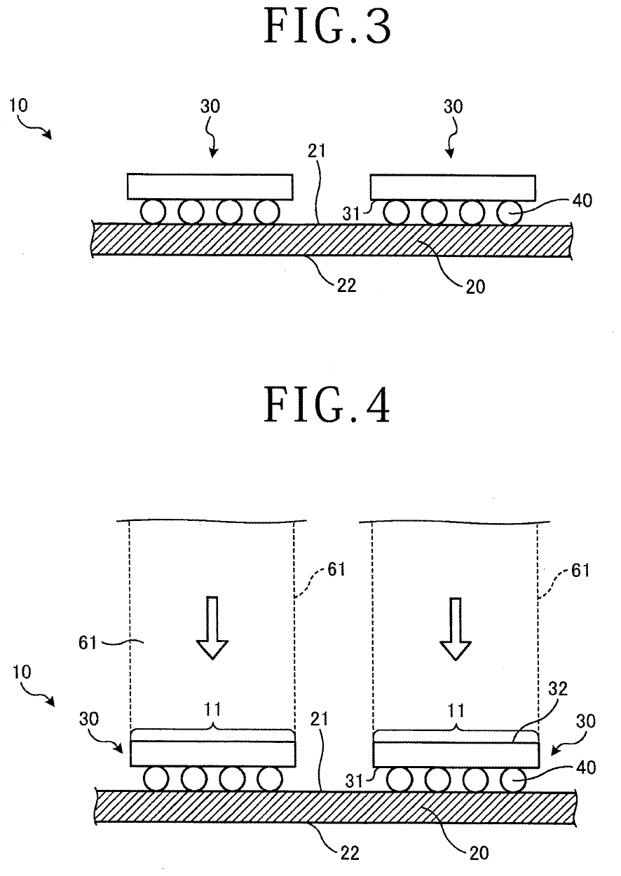

FIG. 2 is a perspective view of a workpiece 10 prepared in the preparation step 1 illustrated in FIG. 1. FIG. 3 is a cross-sectional view of essential parts of the workpiece 10 illustrated in FIG. 2. As illustrated in FIG. 2 and FIG. 3, the workpiece 10 includes a board 20 and semiconductor chips 30 each having bumps 40.

The preparation step 1 is a step of preparing the workpiece 10 having the semiconductor chips 30 placed on the board 20. In this regard, each of the semiconductor chips 30 has one surface (a front surface 31) with bumps 40 formed thereon and another surface (a back surface 32) opposite to the one surface. The board 20 has a front surface 21 and a back surface 22. The semiconductor chips 30 are placed on the front surface 21 side of the board 20 with the bumps 40 interposed therebetween, such that the one surfaces (the front surfaces 31) of the semiconductor chips 30 face downward and the front surface 21 of the board 20 faces upward.

The board 20 in the present embodiment has a rectangular shape. The board 20 is, for example, a printed circuit board (PCB) or a device wafer that is to be divided into chips. The plurality of semiconductor chips 30 are arranged on the front surface 21 side of the board 20 with the bumps 40 interposed therebetween. The semiconductor chips 30 each have a plurality of bumps 40 formed on the front surface 31. The bumps 40 are terminals formed in a manner protruding from the front surface 31 of each semiconductor chip 30.

The semiconductor chips 30 are electrically connected to electrodes on the board 20 when the bumps 40 are heated and melted. That is, the workpiece 10 prepared in the preparation step 1 is scheduled to have the bumps 40 reflowed by a laser beam 61 (refer to FIG. 4) and have the semiconductor chips 30 flip-chip bonded to the board 20.

It is to be noted that the workpiece 10 may be, for example, a workpiece in which the semiconductor chips 30 are arranged on the board 20 with the bumps 40 interposed therebetween as in the present embodiment, or a workpiece in which a plurality of semiconductor chips 30 are stacked and bumps 40 exist between each adjacent ones of the semiconductor chips 30.

(Laser Beam Irradiation Step 2)

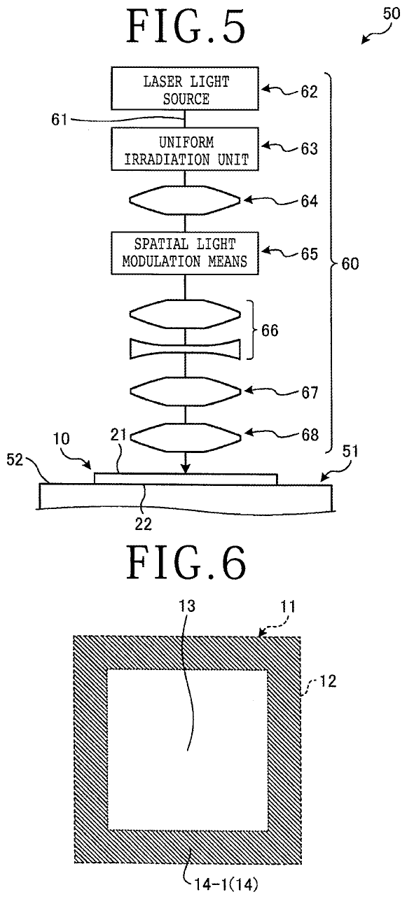

FIG. 4 is a cross-sectional view of the essential parts of the workpiece 10 in a state observed during the laser beam irradiation step 2 illustrated in FIG. 1. FIG. 5 is a view illustrating a configuration example of an optical system of a laser reflow apparatus 50 which carries out the laser beam irradiation step 2 illustrated in FIG. 1. The laser beam irradiation step 2 is a step of irradiating the semiconductor chips 30 with the laser beam 61 to reflow the bumps 40 formed within an irradiated area 11 of the workpiece 10.

The laser beam irradiation step 2 in the present embodiment is carried out by the laser reflow apparatus 50, illustrated in FIG. 5, which has the optical system. The laser reflow apparatus 50 includes a processing table 51, a laser beam irradiation unit 60, a moving unit not illustrated, an imaging unit not illustrated, and a controller not illustrated.

The processing table 51 holds the workpiece 10 on a holding surface 52 thereof. The laser beam irradiation unit 60 causes the laser beam 61 to be applied to the workpiece 10 held on the processing table 51. The moving unit not illustrated moves the processing table 51 and the laser beam irradiation unit 60 relative to each other. The imaging unit not illustrated captures an image of the workpiece 10 held on the processing table 51, and the captured image is used to carry out alignment between a position of the workpiece 10 and a position of an irradiating part for applying the laser beam 61. The controller not illustrated controls the respective constituent elements.

As illustrated in FIG. 5, the laser beam irradiation unit 60 includes a laser light source 62, a uniform irradiation unit 63, a light guide unit 64, spatial light modulation means 65, an image focusing system 66, a magnifying image focusing lens 67, and a telecentric lens 68.

The laser light source 62 emits the laser beam 61. The laser light source 62 is in the form of, for example, a fiber laser, a single light source having a single laser diode (LD), or a multiple light source having a plurality of laser diodes arranged therein. The laser beam 61 emitted from the laser light source 62 is a continuous wave (CW) having a wavelength that can be absorbed by the workpiece 10 (the semiconductor chips 30).

The uniform irradiation unit 63 is arranged at a subsequent stage of the laser light source 62. The uniform irradiation unit 63 acts to form a uniform irradiation surface on the spatial light modulation means 65, which will be described later, with the laser beam 61 emitted from the uniform irradiation unit 63. The laser beam 61 has a uniform power density in the uniform irradiation surface.

In a case where the laser light source 62 is a multiple light source, it is particularly preferable to incorporate the uniform irradiation unit 63 in the laser beam irradiation unit 60. Also in a case where the laser light source 62 is a single light source, if the light source has a Gaussian distribution, the uniform irradiation unit 63 should preferably be incorporated for achieving a complete top-hat distribution. Furthermore, also in a case where the laser light source 62 is a light source having a top-hat distribution, the uniform irradiation unit 63 should preferably be incorporated for achieving a more complete top-hat distribution.

Examples of the uniform irradiation unit 63 include a combination of a collimator lens and an aspherical lens for forming a uniform irradiation surface; a combination of a collimator lens, a diffractive optical element (DOE), and a condensing lens for forming a uniform irradiation surface; a combination of a rod lens (a tubular member made of glass) or a light pipe (a hollow tubular member surrounded by a mirror, also referred to as a homogenizer rod) and a light guide unit (a relay lens or an optical fiber) for forming a uniform irradiation surface; and a combination of a collimator lens, first and second lens arrays (each including an array of rod lenses or a lens having a surface processed into an array of lenses), and a condensing lens for forming a uniform irradiation surface.

The light guide unit 64 is a unit for transferring light from the uniform irradiation surface formed by the uniform irradiation unit 63 to the spatial light modulation means 65. It is to be noted that, in a case where the laser beam irradiation unit 60 does not include the uniform irradiation unit 63, the light guide unit 64 transfers light directly from the laser light source 62 to the spatial light modulation means 65. The light guide unit 64 is, for example, an optical fiber or a relay lens (a set of lenses).

The spatial light modulation means 65 including a spatial light modulation element is capable of controlling a spatial density distribution of an intensity (a power density) of the emitted laser beam 61 and is also referred to as a spatial light modulator (SLM). The spatial light modulation means 65 controls the spatial density distribution of the power density of the laser beam 61 to thereby control a shape of an irradiation range 14 of the laser beam 61 in the irradiated area 11 (refer to FIG. 4 as well as FIG. 6 through FIG. 9 to be described later) of the workpiece 10 when the workpiece 10 is irradiated with the laser beam 61. The spatial light modulation means 65 may be selected from any known SLM devices including a reflective liquid-crystal-on-silicon (LCOS) device, a transmissive liquid-crystal panel (LCP), a deformable mirror, and a digital micro-mirror device (DMD), for example. The spatial light modulation means 65 in the present embodiment is an LCOS device.

The image focusing system 66 focuses an image of the laser beam 61 incident thereon. The image focusing system 66 may be a single lens or an image focusing lens including a set of lenses, and in the example illustrated in FIG. 5, includes a double-convex lens and a double-concave lens that are successively arranged. It is to be noted that, in a case where the spatial light modulation element of the spatial light modulation means 65 also has a function as the image focusing system 66 (the image focusing lens), the image focusing system 66 may be omitted.

The magnifying image focusing lens 67 magnifies an image (a conjugate image) focused by the image focusing system 66 and focuses the magnified image on the laser-irradiated surface (the irradiated area 11) of the workpiece 10. It is to be noted that the magnifying image focusing lens 67 may be omitted.

The telecentric lens 68 causes the laser beam 61 to enter the laser-irradiated surface (the irradiated area 11) of the workpiece 10 perpendicularly, i.e., in parallel to its optical axis. It is to be noted that the image focusing system 66 may be configured as the telecentric lens 68, and alternatively, the optical system may be configured such that the telecentric lens 68 is omitted therefrom.

The laser beam irradiation unit 60 in the present embodiment has image focusing means, which includes the image focusing system 66, the magnifying image focusing lens 67, and the telecentric lens 68, and focus an image of the laser beam 61 in an area corresponding to the back surface 32 of each semiconductor chip 30 in the workpiece 10 held on the processing table 51. It is to be noted that, in the laser beam irradiation unit 60, laser irradiation may be carried out simultaneously for a plurality of semiconductor chips 30.

In the laser beam irradiation step 2, first, the workpiece 10 is held on the holding surface 52 of the processing table 51. In this case, the holding surface 52 holds the back surface 22 side of the board 20, and the semiconductor chips 30 are placed on the front surface 21 side of the board 20 with the bumps 40 interposed therebetween. Next, the imaging unit not illustrated captures an image of the workpiece 10 held on the processing table 51, and the moving unit not illustrated moves the processing table 51 and the laser beam irradiation unit 60 relative to each other to carry out alignment between the position of the workpiece 10 and the position of the irradiating part of the laser beam irradiation unit 60.

In the laser beam irradiation step 2, the semiconductor chips 30 are irradiated with the laser beam 61 from the back surface 32 side. In this case, the irradiated area 11 irradiated with the laser beam 61 corresponds to the entire back surface 32 of each semiconductor chip 30. In the laser beam irradiation step 2 in the present embodiment, the irradiated area 11 is irradiated with the laser beam 61 for one second.

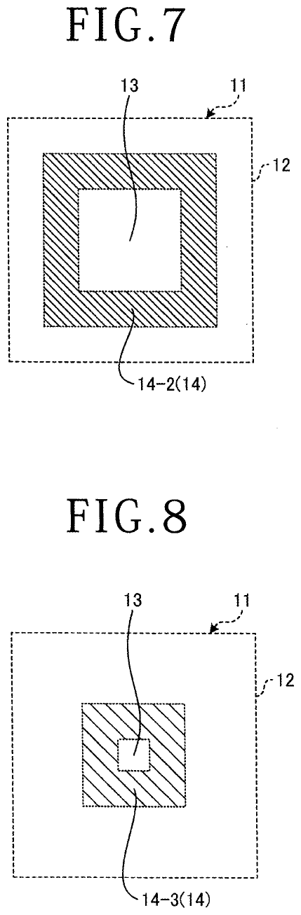

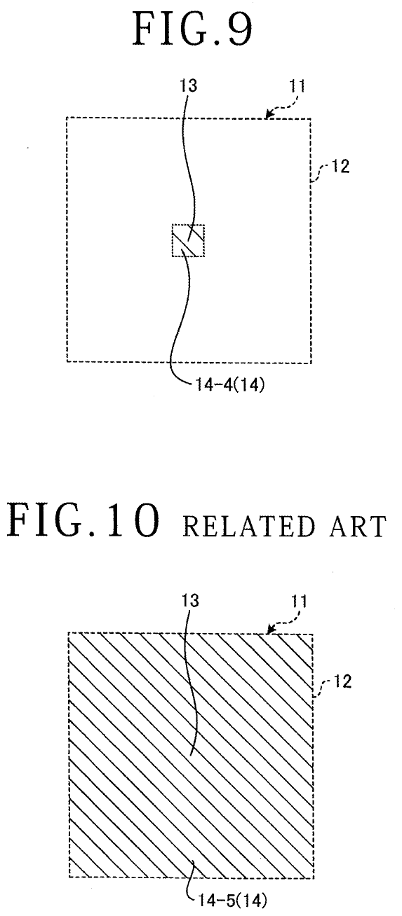

FIG. 6 is a plan view illustrating a first-stage irradiation range 14-1 in the irradiated area 11 of the workpiece 10. FIG. 7 is a plan view illustrating a second-stage irradiation range 14-2 in the irradiated area 11 of the workpiece 10. FIG. 8 is a plan view illustrating a third-stage irradiation range 14-3 in the irradiated area 11 of the workpiece 10. FIG. 9 is a plan view illustrating a fourth-stage irradiation range 14-4 in the irradiated area 11 of the workpiece 10.

In the laser beam irradiation step 2, as illustrated in FIG. 6 through FIG. 9, the irradiated area 11 is irradiated with the laser beam 61 while the irradiation range 14 of the laser beam 61 is changed in stages. In the laser beam irradiation step 2 in the present embodiment, irradiation with the laser beam 61 is carried out in four stages in a divided manner. It is to be noted that, in the present embodiment, the irradiation range 14 of the laser beam 61 is changed by the spatial light modulation means 65 controlling the spatial density distribution of the power density of the laser beam 61.

Specifically, after the alignment between the position of the workpiece 10 and the position of the irradiating part of the laser beam irradiation unit 60 is carried out, in the laser beam irradiation step 2, the spatial light modulation means 65 changes the shape of the irradiation range 14 of the laser beam 61 to the first-stage irradiation range 14-1 illustrated in FIG. 6.

As illustrated in FIG. 6, the first-stage irradiation range 14-1 of the laser beam 61 includes an outer peripheral portion 12 of the irradiated area 11. The outer peripheral portion 12 is an annular region at and in the vicinity of an outer peripheral edge of the irradiated area 11 and corresponds to an outer peripheral portion of each semiconductor chip 30. The first-stage irradiation range 14-1 in the present embodiment is in the form of a rectangular frame along an outer peripheral edge of each semiconductor chip 30 that has a rectangular shape.

In the laser beam irradiation step 2, with the first-stage irradiation range 14-1 irradiated with the laser beam 61, the bumps 40 formed in a region that includes the outer peripheral portion 12 and corresponds to the first-stage irradiation range 14-1 are reflowed, so that the annular (rectangular) part of the semiconductor chip 30, which part corresponds to the first-stage irradiation range 14-1 and includes the outer peripheral portion 12, is bonded to the board 20.

In the laser beam irradiation step 2, next, the spatial light modulation means 65 changes the shape of the irradiation range 14 of the laser beam 61 to the second-stage irradiation range 14-2 illustrated in FIG. 7. As illustrated in FIG. 7, the second-stage irradiation range 14-2 of the laser beam 61 is an annular region that is adjacent to the first-stage irradiation range 14-1 illustrated in FIG. 6 on an inner side of the first-stage irradiation range 14-1. The second-stage irradiation range 14-2 in the present embodiment is in the form of a rectangular frame.

In the laser beam irradiation step 2, with the second-stage irradiation range 14-2 irradiated with the laser beam 61 after the first-stage irradiation range 14-1 is irradiated with the laser beam 61, the bumps 40 formed in a region corresponding to the second-stage irradiation range 14-2 are reflowed, so that the annular (rectangular) part of the semiconductor chip 30, which part corresponds to the second-stage irradiation range 14-2 and is disposed on an inner side of the outer peripheral portion 12, is bonded to the board 20 subsequently to the outer peripheral portion 12.

In the laser beam irradiation step 2, next, the spatial light modulation means 65 changes the shape of the irradiation range 14 of the laser beam 61 to the third-stage irradiation range 14-3 illustrated in FIG. 8. As illustrated in FIG. 8, the third-stage irradiation range 14-3 of the laser beam 61 is an annular region that is adjacent to the second-stage irradiation range 14-2 illustrated in FIG. 7 on an inner side of the second-stage irradiation range 14-2. The third-stage irradiation range 14-3 in the present embodiment is in the form of a rectangular frame.

In the laser beam irradiation step 2, with the third-stage irradiation range 14-3 irradiated with the laser beam 61 after the second-stage irradiation range 14-2 is irradiated with the laser beam 61, the bumps 40 formed within a region corresponding to the third-stage irradiation range 14-3 are reflowed, so that the annular (rectangular) part of the semiconductor chip 30, which part corresponds to the third-stage irradiation range 14-3 and is disposed on the inner side of the second-stage irradiation range 14-2, is bonded to the board 20 subsequently to the part corresponding to the second-stage irradiation range 14-2.

In the laser beam irradiation step 2, next, the spatial light modulation means 65 changes the shape of the irradiation range 14 of the laser beam 61 to the fourth-stage irradiation range 14-4 illustrated in FIG. 9. As illustrated in FIG. 9, the fourth-stage irradiation range 14-4 of the laser beam 61 is adjacent to the third-stage irradiation range 14-3 illustrated in FIG. 8 on an inner side of the third-stage irradiation range 14-3 and includes a central portion 13 of the irradiated area 11. The central portion 13 is a region corresponding to a central portion of the semiconductor chip 30. The fourth-stage irradiation range 14-4 in the present embodiment is in the form of a rectangle.

In the laser beam irradiation step 2, with the fourth-stage irradiation range 14-4 irradiated with the laser beam 61 after the third-stage irradiation range 14-3 is irradiated with the laser beam 61, the bumps 40 formed within a region which includes the central portion 13 and corresponds to the fourth-stage irradiation range 14-4 are reflowed, so that the rectangular part of the semiconductor chip 30, which part includes the central portion 13 and corresponds to the fourth-stage irradiation range 14-4, is bonded to the board 20 subsequently to the part corresponding to the third-stage irradiation range 14-3.

In this manner, in the laser beam irradiation step 2, the irradiated area 11 of the workpiece 10 is irradiated with the laser beam 61 during an irradiation time, i.e., one second in the present embodiment, while the irradiation range 14 is being changed in stages from the region including the outer peripheral portion 12 to the region including the central portion 13. In the laser beam irradiation step 2, the bumps 40 formed within the irradiated area 11 are thus reflowed successively from the outer peripheral portion 12 toward the central portion 13 of the semiconductor chip 30.

In the laser beam irradiation step 2, the power density of the laser beam 61 may be changed in association with the change of the irradiation range 14. In this case, the power density is set such that the power density of the laser beam 61 applied to the region including the outer peripheral portion 12 is larger than the power density of the laser beam 61 applied to the region including the central portion 13.

In a case where the irradiation range 14 is changed in three stages or more, the power density may be changed every time the irradiation range 14 is changed or may be changed at the time of at least one of the changes of the irradiation range 14. More specifically, the power density may be set such that, with the irradiation range 14 changed in stages, the power density of the laser beam 61 applied to a predetermined irradiation range 14 (the third-stage irradiation range 14-3, for example) is equal to or smaller than the power density of the laser beam 61 applied to another irradiation range 14 (the second-stage irradiation range 14-2, for example) which is closer to the outer peripheral portion 12 than the predetermined irradiation range 14. In this case, as for the power density of the laser beam 61 applied to the irradiation range 14 in the present embodiment, the following relation is established. (Power density of the first-stage irradiation range 14-1) (Power density of the second-stage irradiation range 14-2) (Power density of the third-stage irradiation range 14-3) (Power density of the fourth-stage irradiation range 14-4).

Alternatively, the power density may successively be reduced from the outer peripheral portion 12 toward the central portion 13. In this case, as for the power density of the laser beam 61 applied to the irradiation range 14 in the present embodiment, the following relation is established. (Power density of the first-stage irradiation range 14-1)>(Power density of the second-stage irradiation range 14-2)>(Power density of the third-stage irradiation range 14-3)>(Power density of the fourth-stage irradiation range 14-4).

FIG. 10 is a plan view illustrating an irradiation range 14-5 according to a comparative example. The irradiation range 14-5 in the comparative example includes the entire irradiated area 11. That is, in the laser beam irradiation step 2 in the comparative example, the irradiated area 11 is uniformly irradiated with the laser beam 61 for one second. In the comparative example, since the outer peripheral portion 12 of the semiconductor chip 30 is exposed to outside air and is apt to release heat, the temperature rise in the outer peripheral portion 12 is slow compared to that in the central portion 13. Therefore, when the bumps 40 are reflowed in the laser beam irradiation step 2 in the comparative example, the semiconductor chip 30 is bonded to the board 20 first at the central portion 13, which leads to a chip warpage.

In contrast, with the laser reflow method according to the present embodiment, in the laser beam irradiation step 2, irradiation with the laser beam 61 is carried out in stages from the outer peripheral portion 12 to the central portion 13. Accordingly, the semiconductor chip 30 can be bonded to the board 20 at the outer peripheral portion 12 earlier than at the central portion 13, so that occurrence of a chip warpage caused when the semiconductor chip 30 is bonded to the board 20 first at the central portion 13 can be restrained. Consequently, it is possible to restrain connection failures from occurring at the outer peripheral portions 12 of the semiconductor chips 30.

It is to be noted that the present invention is not limited to the embodiment described above. That is, various changes of the embodiment may be made without departing from the gist of the present invention. For example, while the irradiation range 14 of the laser beam 61 is changed by using the spatial light modulation means 65 (LCOS) in the above embodiment, the irradiation range 14 may be changed by mechanically moving a mask prepared in advance for shielding part of the laser beam 61.

Further, as for the plurality of irradiation ranges 14 changed in stages, an irradiation range 14 (the second-stage irradiation range 14-2, for example) on the outer peripheral portion 12 side is adjacent to another irradiation range 14 (the third-stage irradiation range 14-3, for example) on the central portion 13 side in the above embodiment. Alternatively, in the present invention, the irradiation range 14 on the outer peripheral portion 12 side and the irradiation range 14 on the central portion 13 side may be set to partly overlap each other.

The present invention is not limited to the details of the above-described preferred embodiment. The scope of the invention is defined by the appended claims and all changes and modifications as fall within the equivalence of the scope of the claims are therefore to be embraced by the invention.

What is claimed is:

1. A laser reflow method comprising:
a preparation step of preparing a workpiece including a board and semiconductor chips that each have bumps formed on one surface thereof and are placed on the board with the bumps interposed therebetween; and
a laser beam irradiation step of irradiating the semiconductor chips with a laser beam from a side of another surface opposite to the one surface, thereby reflowing bumps formed within an irradiated area of the workpiece,
wherein, in the laser beam irradiation step, the irradiation with the laser beam is carried out while an irradiation range of the laser beam is changed in stages from a region including an outer peripheral portion of the irradiated area toward a region including a central portion of the irradiated area.

2. The laser reflow method according to claim 1, wherein, in the laser beam irradiation step, a power density of the laser beam is changed in association with the change of the irradiation range.

3. The laser reflow method according to claim 2, wherein, in the laser beam irradiation step, the power density is set such that, with the irradiation range changed in stages, the power density of the laser beam applied to a predetermined irradiation range is equal to or smaller than the power density of the laser beam applied to another irradiation range that is closer to the outer peripheral portion than the predetermined irradiation range.
